(19) United States
(12) Patent Application Publication
(10) Pub. No.: US 2026/0194166 A1
(43) Pub. Date: Jul. 9, 2026

(54) ANTI-LOOSENING MECHANISM FOR A PIPE COMPONENT AND A PIPE FITTING AT LEAST PARTIALLY REMOVABLY INSERTED INTO THE PIPE COMPONENT, RELATED PIPE ASSEMBLY AND RELATED CABINET SYSTEM

(71) Applicant: Wiwynn Corporation, New Taipei City (TW)

(72) Inventors: Yu-Hsuan Wang, New Taipei City (TW); Wei-Hao Chen, New Taipei City (TW)

(73) Assignee: Wiwynn Corporation, New Taipei City (TW)

(21) Appl. No.: 19/298,225

(22) Filed: Aug. 13, 2025

(30) Foreign Application Priority Data
Jan. 7, 2025 (TW) 114100562

(51) Int. Cl. F16L 19/07; H05K 7/20

(52) U.S. Cl. CPC F16L 19/07; H05K 7/20254

(57) ABSTRACT

An anti-loosening mechanism for a pipe component and a pipe fitting at least partially removably inserted into the pipe component is provided, and includes an outer case, an operating component and a clamping component. The outer case is configured to be removably mounted on the pipe fitting. The operating component is rotatable. The clamping component is at least partially movably sleeved inside the operating component and includes a plurality of clamping portions. When the operating component rotates, the operating component drives each of the clamping portions to move along an clamping direction by a cooperation of a driving structure of the operating component and a driving cooperating structure of each of the clamping portions, such that the pipe component is clamped by and between each of the plurality of clamping portions and the pipe fitting. Besides, a related pipe assembly and a related cabinet system are also provided.

### BACKGROUND OF THE INVENTION

### 1. FIELD OF THE INVENTION

The present invention relates to a pipe accessory, a related pipe assembly and a related cabinet system, and more specifically, to an anti-loosening mechanism for a pipe component and a pipe fitting at least partially removably inserted into the pipe component, a related pipe assembly and a related cabinet system.

### 2. DESCRIPTION OF THE PRIOR ART

With increasing demand for high-performance computing systems and artificial intelligence applications, liquid cooling solutions have gradually replaced air cooling solutions and become a mainstream trend because the liquid cooling solutions provide higher heat dissipation efficiency. However, coolant leakage may cause a short circuit or damage of an apparatus and usually occurs at a connection between a pipe component and a pipe fitting. Therefore, it becomes an important topic in the field to prevent coolant leakage.

### SUMMARY OF THE INVENTION

It is an objective of the present invention to provide an anti-loosening mechanism for a pipe component and a pipe fitting at least partially removably inserted into the pipe component, a related pipe assembly and a related cabinet system for solving the aforementioned problems.

In order to achieve the aforementioned objectives, the present invention discloses an anti-loosening mechanism for a pipe component and a pipe fitting at least partially removably inserted into the pipe component. The anti-loosening mechanism includes an outer case, an operating component and a clamping component. The outer case is configured to be removably mounted on the pipe fitting. The operating component is rotatable relative to the outer case around a rotating axis. The operating component includes a driving structure. The clamping component is at least partially movably sleeved inside the operating component. The clamping component includes a plurality of clamping portions. Each of the plurality of clamping portions includes a driving cooperating structure, and when the operating component rotates relative to the outer case around the rotating axis, the operating component drives each of the plurality of clamping portions to move relative to the outer case along an clamping direction by a cooperation of the driving structure of the operating component and the driving cooperating structure of each of the plurality of clamping portions, such that the pipe component is clamped by and between each of the plurality of clamping portions and the pipe fitting.

Besides, in order to achieve the aforementioned objectives, the present invention further discloses a pipe assembly. The pipe assembly includes a pipe component, a pipe fitting and an anti-loosening mechanism. The pipe fitting is at least partially removably inserted into the pipe component. The anti-loosening mechanism includes an outer case, an operating component and a clamping component. The outer case is configured to be removably mounted on the pipe fitting. The operating component is rotatable relative to the outer case around a rotating axis. The operating component includes a driving structure. The clamping component is at least partially movably sleeved inside the operating component. The clamping component includes a plurality of clamping portions. Each of the plurality of clamping portions includes a driving cooperating structure, and when the operating component rotates relative to the outer case around the rotating axis, the operating component drives each of the plurality of clamping portions to move relative to the outer case along an clamping direction by a cooperation of the driving structure of the operating component and the driving cooperating structure of each of the plurality of clamping portions, such that the pipe component is clamped by and between each of the plurality of clamping portions and the pipe fitting.

Additionally, in order to achieve the aforementioned objectives, the present invention further discloses a cabinet system. The cabinet system includes a cabinet body, an electronic device and a pipe assembly. The electronic device is detachably mounted on the cabinet body. The electronic device includes a connecting portion. The pipe assembly includes a pipe component, a pipe fitting and an anti-loosening mechanism. The pipe fitting is at least partially removably inserted into the pipe component. The anti-loosening mechanism includes an outer case, an operating component and a clamping component. The outer case is configured to be removably mounted on the pipe fitting. The operating component is rotatable relative to the outer case around a rotating axis. The operating component includes a driving structure. The clamping component is at least partially movably sleeved inside the operating component. The clamping component includes a plurality of clamping portions. Each of the plurality of clamping portions includes a driving cooperating structure, and when the operating component rotates relative to the outer case around the rotating axis, the operating component drives each of the plurality of clamping portions to move relative to the outer case along an clamping direction by a cooperation of the driving structure of the operating component and the driving cooperating structure of each of the plurality of clamping portions, such that the pipe component is clamped by and between each of the plurality of clamping portions and the pipe fitting.

In contrast to the prior art, in the present invention, it only has to rotate the operating component by hands to operate the anti-loosening mechanism without any additional tool, such as a screw driver. Therefore, the present invention provides improved operational convenience and is suitable for use in a confined mechanical space. Besides, in the present invention, the configuration, which utilizes the operating component to drive the clamping portion to clamp the pipe component between and by the clamping portion and the pipe fitting, not only prevents disengagement of the pipe component and the pipe fitting but also prevents any fracture or rupture of the pipe component due to stress concentration caused by an improper force application. Therefore, the present invention also provides enhanced reliability.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a partial internal structural diagram of a cabinet system according to an embodiment of the present invention.

FIG. 2 is a partial exploded diagram of the cabinet system according to the embodiment of the present invention.

FIG. 3 and FIG. 4 are sectional diagrams of a pipe assembly in different states according to the embodiment of the present invention.

FIG. 5 and FIG. 6 are assembling diagrams of an anti-loosening mechanism at different views according to the embodiment of the present invention.

FIG. 7 and FIG. 8 are exploded diagrams of the anti-loosening mechanism at different views according to the embodiment of the present invention.

FIG. 9 is a partial structural diagram of the anti-loosening mechanism according to the embodiment of the present invention.

FIG. 10 is another partial structural diagram of the anti-loosening mechanism according to the embodiment of the present invention.

FIG. 11 and FIG. 12 are partial enlarged structural diagrams of the anti-loosening mechanism with an engaging component at different positions according to the embodiment of the present invention.

### DETAILED DESCRIPTION

In the following detailed description of the preferred embodiments, reference is made to the accompanying drawings which form a part hereof, and in which is shown by way of illustration specific embodiments in which the invention may be practiced. In this regard, directional terminology, such as “top”, “bottom”, “left”, “right”, “front”, “back”, etc., is used with reference to the orientation of the Figure(s) being described. The components of the present invention can be positioned in a number of different orientations. As such, the directional terminology is used for purposes of illustration and is in no way limiting. Accordingly, the drawings and descriptions will be regarded as illustrative in nature and not as restrictive. Also, if not specified, the term “connect” is intended to mean either an indirect or direct mechanical connection. Thus, if a first device is connected to a second device, that connection may be through a direct mechanical connection, or through an indirect mechanical connection via other devices and connections.

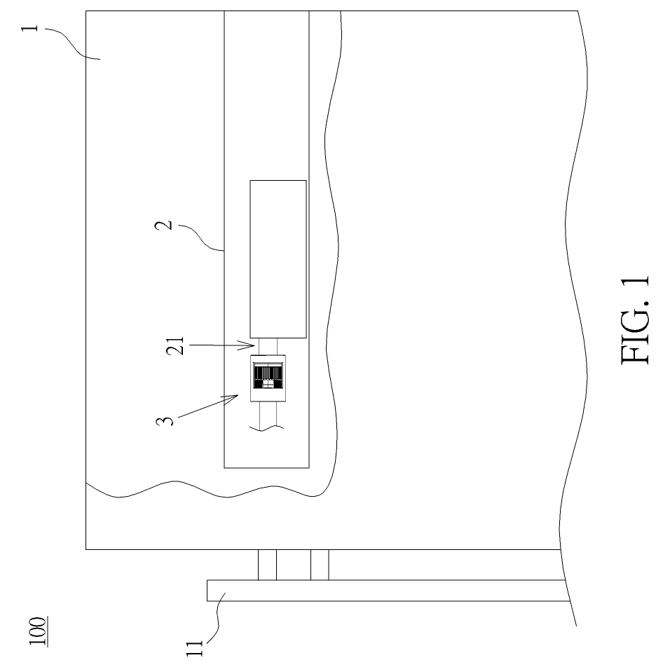

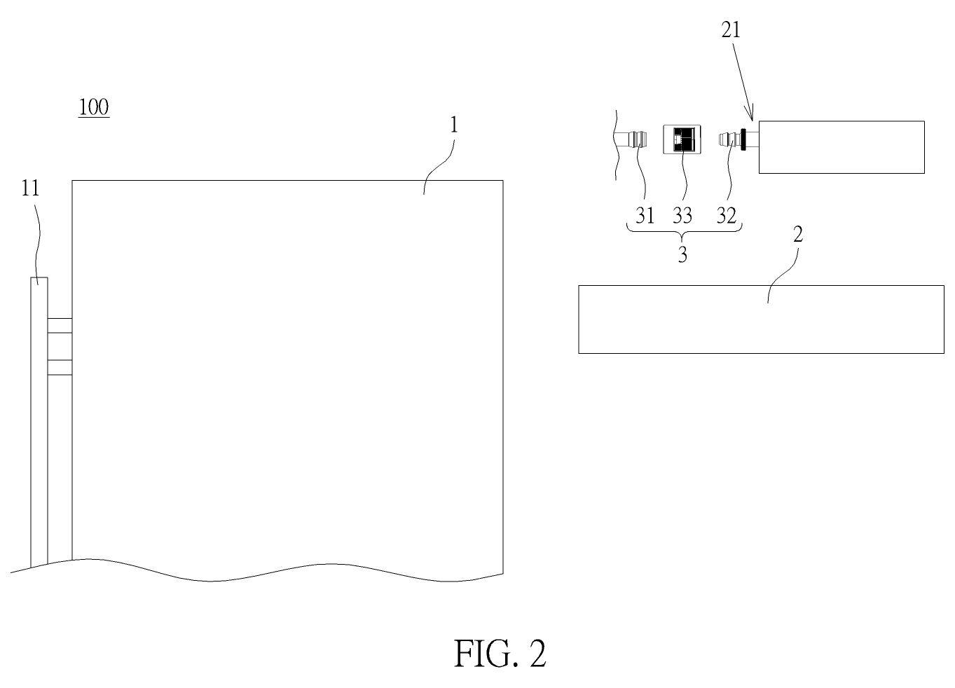

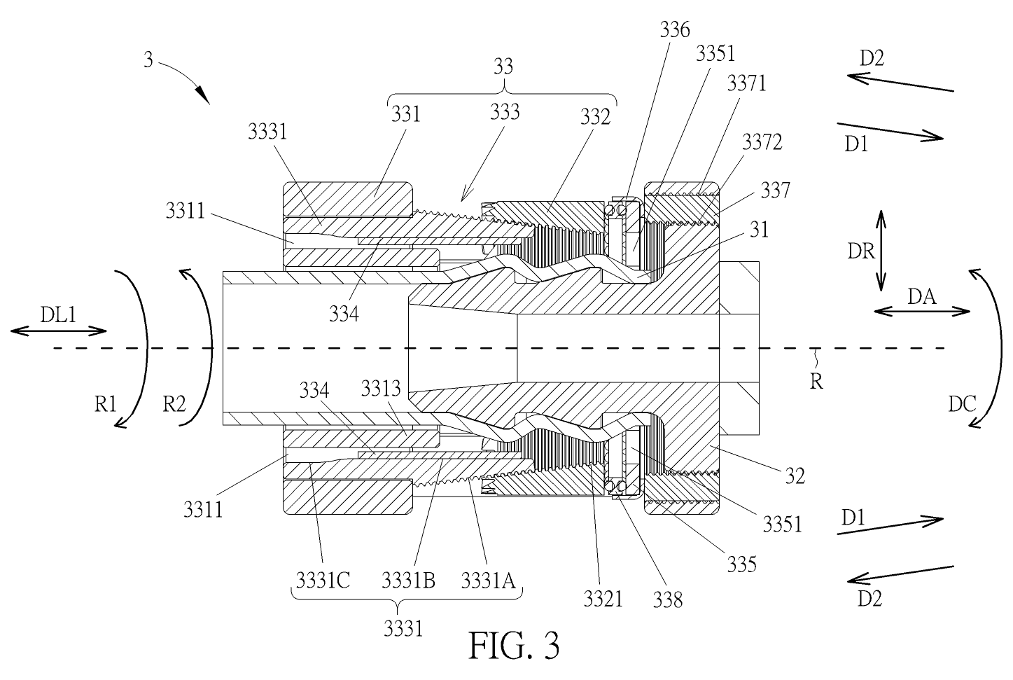

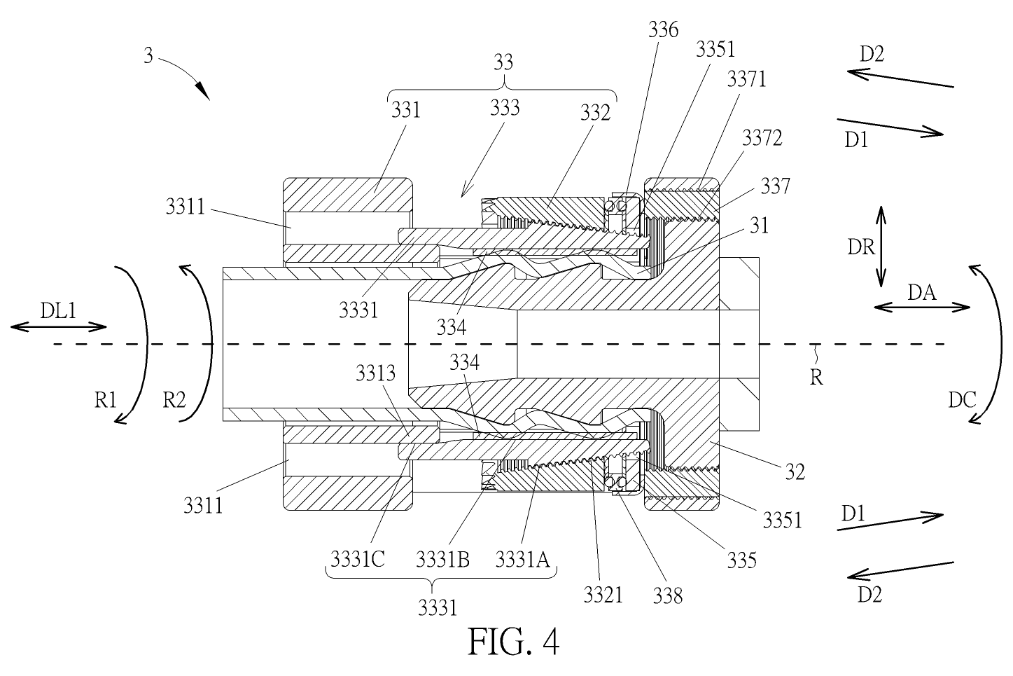

Please refer to FIG. 1 to FIG. 4. FIG. 1 is a partial internal structural diagram of a cabinet system 100 according to an embodiment of the present invention. FIG. 2 is a partial exploded diagram of the cabinet system 100 according to the embodiment of the present invention. FIG. 3 and FIG. 4 are sectional diagrams of a pipe assembly 3 in different states according to the embodiment of the present invention. As shown in FIG. 1 to FIG. 4, the cabinet system 100 includes a cabinet body 1, an electronic device 2 and the pipe assembly 3. The electronic device 2 is detachably mounted on the cabinet body 1. The electronic device 2 includes a connecting portion 21. The pipe assembly 3 includes a pipe component 31, a pipe fitting 32 and an anti-loosening mechanism 33. The pipe fitting 32 is connected to the connecting portion 21 of the electronic device 2 and at least partially removably inserted into the pipe component 31. The anti-loosening mechanism 33 is configured to secure a connection between the pipe component 31 and the pipe component 31 for preventing disengagement of the pipe component 31 and the pipe fitting 32. In this embodiment, by way of example, the cabinet system 100 can be a server cabinet system, and the electronic device 2 can be a computing device having at least one processor and at least one coolant pipe. The electronic device 2 can be a liquid cooling server, such as, but not limited to, a cold plate cooling server. Besides, in this embodiment, the connecting portion 21 can be a connecting port of the coolant pipe of the computing device, and the pipe component 31 can be communicated with a coolant distribution pipe 11 arranged near a rear side of the cabinet body 1 to allow coolant to flow from the coolant distribution pipe 11 to an interior of the computing device for cooling the processor of the computing device. However, the present invention is not limited to this embodiment. It should be noticed that the locations and the numbers of the pipe assembly 3 of the present invention are not limited to those illustrated in FIG. 1 and FIG. 2. In this embodiment, the pipe assembly 3 is configured to connect the coolant pipe inside a chassis body of the electronic device 2. In another embodiment, there can be one or more pipe assemblies 3 arranged outside the cabinet body 1 for connecting external pipes outside the cabinet body 1, or arranged inside the cabinet body 1 for connecting internal pipes inside the cabinet body. However, the present invention is not limited to the aforementioned embodiments.

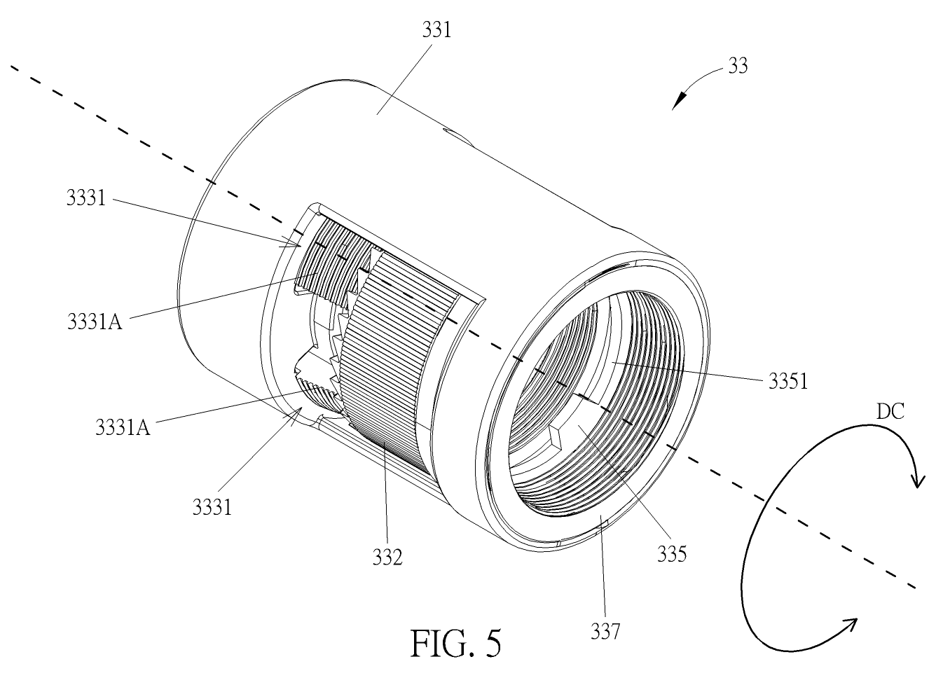

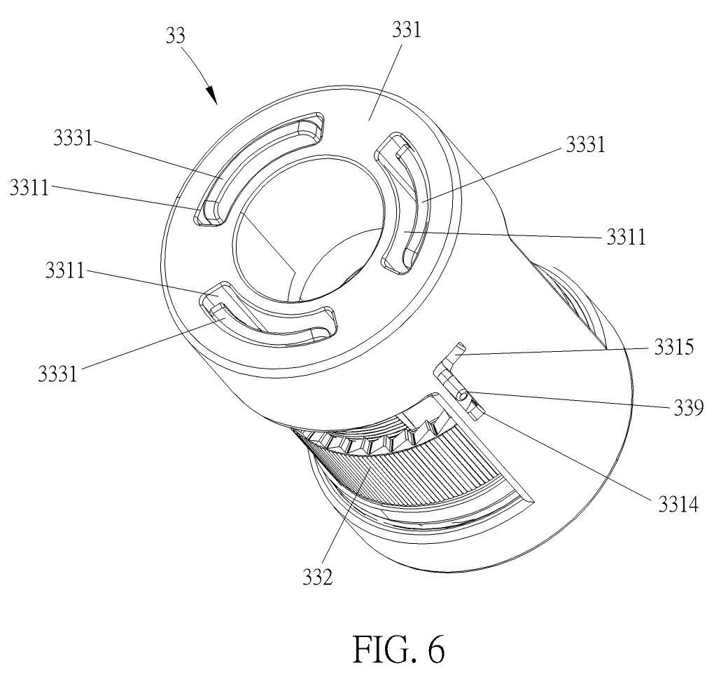

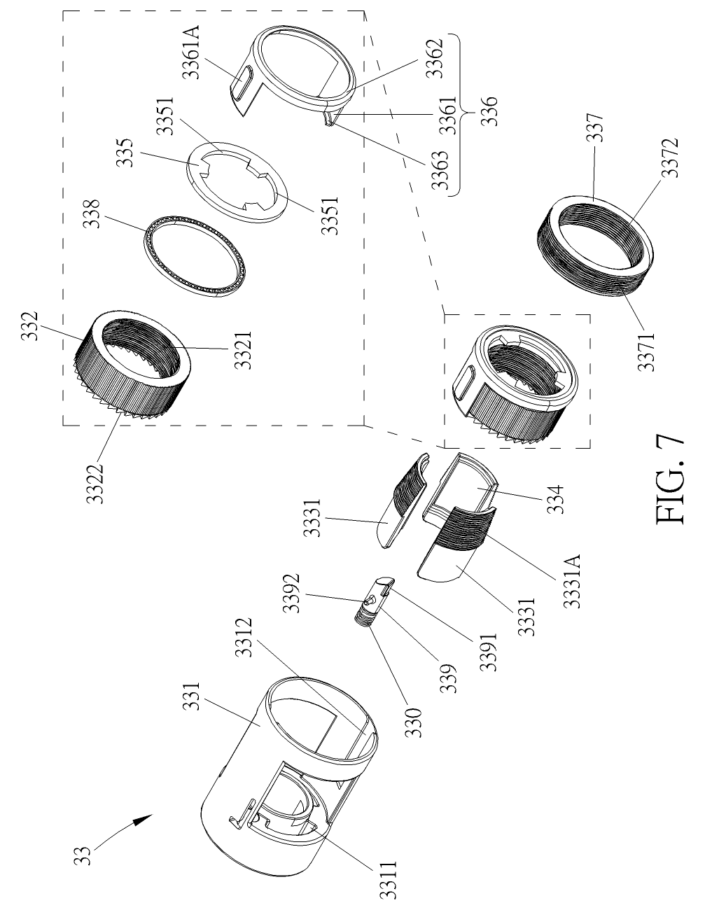

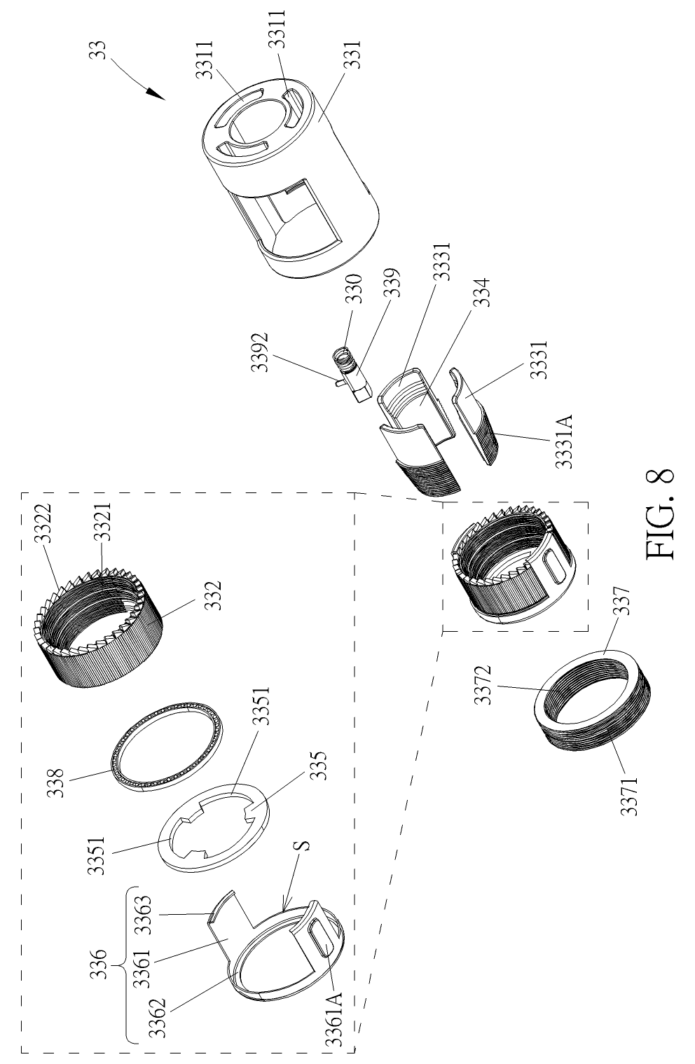

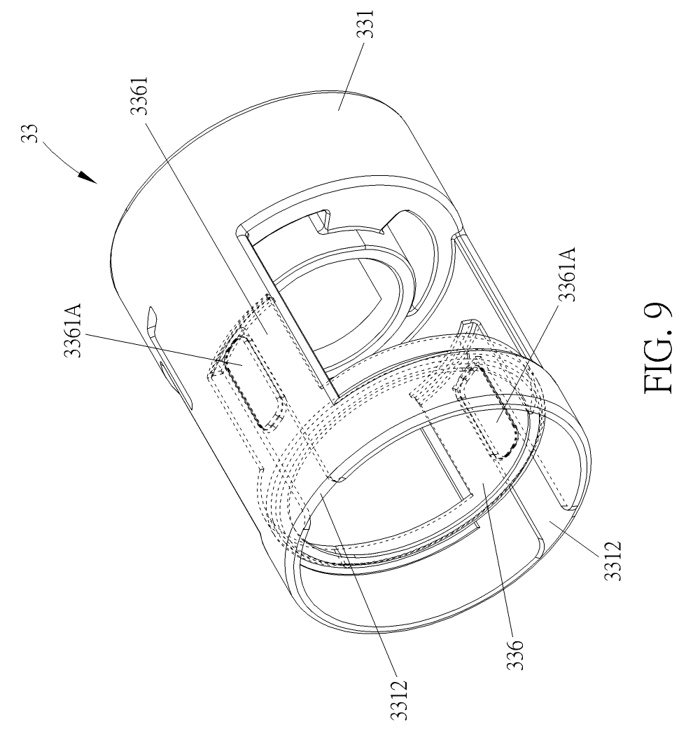

Please refer to FIG. 3 to FIG. 9. FIG. 5 and FIG. 6 are assembling diagrams of the anti-loosening mechanism 33 at different views according to the embodiment of the present invention. FIG. 7 and FIG. 8 are exploded diagrams of the anti-loosening mechanism 33 at different views according to the embodiment of the present invention. FIG. 9 is a partial structural diagram of the anti-loosening mechanism 33 according to the embodiment of the present invention. As shown in FIG. 3 to FIG. 9, the anti-loosening mechanism 33 includes an outer case 331, an operating component 332 and a clamping component 333. The outer case 331 is configured to be removably mounted on the pipe fitting 32. The operating component 332 is rotatable relative to the outer case 331 around a rotating axis R. The operating component 332 includes a driving structure 3321. The clamping component 333 is at least partially movably sleeved inside the operating component 332. The clamping component 333 includes three clamping portions 3331. Each of the clamping portions 3331 includes a driving cooperating structure 3331A. When the operating component 332 rotates relative to the outer case 331 around the rotating axis R, the operating component 332 drives each of the clamping portions 3331 to move relative to the outer case 331 along a corresponding clamping direction D1 by a cooperation of the corresponding driving structure 3321 and the corresponding driving cooperating structure 3331A, such that the pipe component 31 is clamped by and between each of the clamping portions 3331 and the pipe fitting 32.

Specifically, each of the clamping portions 3331 further includes a clamping structure 3331B configured to clamp the pipe component 31 cooperatively with the pipe fitting 32.

In this embodiment, the driving structure 3321 of each of the clamping portions 3331 is an inner tapered threaded structure, and the driving cooperating structure 3331A is an outer tapered threaded structure. Besides, the clamping direction D1 is inclined relative to an axial direction DA and a radial direction DR of the pipe fitting 32, and an axial direction DL1 of the rotating axis R is parallel to the axial direction DA of the pipe fitting 32. However, the present invention is not limited to this embodiment. For example, in another embodiment, the driving structure and the driving cooperating structure can be an inner cylindrical threaded structure and an outer cylindrical threaded structure, respectively, for enabling each of the clamping portions to move along a direction parallel to the axial direction of the pipe fitting, and the clamping structure of each of the clamping portions and the pipe fitting can clamp the pipe component cooperatively by a gradually decreasing inner periphery and/or a resilient deformation of the clamping structure when each of the clamping portions moves along the direction parallel to the axial direction of the pipe fitting.

Preferably, the anti-loosening mechanism 33 further includes three buffering components 334, and each of the buffering components 334 is disposed on the corresponding clamping portion 3331 and configured to abut against the pipe component 31 for preventing any wear or tear damage of the pipe component 31 due to a direct contact or compression of the corresponding clamping portion 3331 and the pipe component 31. Specifically, the buffering component 334 can be made of rubber, foam or any other elastic or deformable material. However, the present invention is not limited thereto.

In order to ensure each of the buffering components 334 to move relative to the outer case 331 along the corresponding clamping direction D1 correctly, three guiding slots 3311 are formed on the outer case 3311 and configured to allow the three clamping portions 3331 to at least partially pass therethrough. The anti-loosening mechanism 33 further includes a guiding component 335, and three guiding notches 3351 are formed on the guiding component 335 and configured to allow the clamping portions 3331 to at least partially pass therethrough. Each of the guiding slots 3311 and each of the guiding notches 3351 can guide two opposite ends of the corresponding clamping portion 3331 for preventing a movement of the corresponding clamping portion 3331 along a circumferential direction DC of the pipe fitting 32.

Understandably, the numbers of the clamping portion, the buffering component, the guiding slot and the guiding notch are not limited to this embodiment. It depends on practical demands. For example, in another embodiment, the clamping component can include two clamping portions, the anti-loosening mechanism can include two buffering components, and the guiding component and the outer case can be provided with two guiding notches and two guiding slots, respectively.

In addition, the anti-loosening mechanism 33 further includes a positioning bracket 336 configured to position the operating component 332 and the guiding component 335 on the outer case 331.

As shown in FIG. 7 to FIG. 9, the positioning bracket 336 includes a lateral wall 3361, a first wall 3362 and a second wall 3363. The lateral wall 3361 is connected between and perpendicular to the first wall 3362 and the second wall 3363, and the lateral wall 3361, the first wall 3362 and the second wall 3363 of the positioning bracket 336 cooperatively form a positioning space S configured to position the operating component 332 and the guiding component 335. Besides, at least one first positioning structure 3361A is formed on the lateral wall 3361. At least one second positioning structure 3312 is formed on the outer case 331. The positioning bracket 336 is positioned on the outer case 331 and prevented from rotating relative to the outer case 331 by a cooperation of the at least one first positioning structure 3361A and the at least one second positioning structure 3312. In this embodiment, the first positioning structure 3361A and the second positioning structure 3312 can be a sliding block structure and a sliding slot structure, respectively. However, the present invention is not limited to this embodiment. For example, in another embodiment, the first positioning structure and the second positioning structure can be an engaging hook structure and an engaging slot structure, respectively.

Moreover, as shown in FIG. 3 to FIG. 5 and FIG. 7 to FIG. 8, in order to achieve the assembly and the positioning of the outer case 331 and the pipe fitting 32, the anti-loosening mechanism 33 further includes a mounting component 337, and the mounting component 337 includes a first combining structure 3371 configured to separably combine with the outer case 331, and a second combining structure 3372 configured to separably combine with the pipe fitting 32. In this embodiment, the first combining structure 3371 and the second combining structure 3372 can be an outer threaded structure and an inner threaded structure, respectively. However, the present invention is not limited to this embodiment. For example, in another embodiment, the first combining structure and the second combining structure can be an outer spline structure and an inner spline structure configured to separably combine with the outer case and the pipe fitting, respectively.

As shown in FIG. 3 to FIG. 4 and FIG. 7 to FIG. 8, the anti-loosening mechanism 33 further includes an auxiliary component 338 disposed between the operating component 332 and the guiding component 335 and configured to prevent a frictional contact between the operating component 332 and the guiding component 335 for ensuring a smooth rotation of the operating component 332. In this embodiment, the auxiliary component 338 can be a ball bearing. However, the present invention is not limited to this embodiment. For example, in another embodiment, the auxiliary component can be a graphite ring.

Furthermore, in order to prevent any fracture or rupture of the pipe component 31 due to an excessive stress application, each of the clamping portions 3331 further includes an abutting structure 3331C. The outer case 331 includes an abutting cooperating structure 3313. The abutting structure 3331C is configured to abut against the abutting cooperating structure 3313 for preventing each of the clamping portions 3331 from overly moving relative to the outer case 331 along the corresponding clamping direction D1. Specifically, the abutting structure 3331C of each of the clamping portions 3331 is disposed adjacent to an outer side of the abutting cooperating structure 3313. The abutting cooperating structure 3313 is configured to abut against the abutting structure 3331C along the radial direction DR of the pipe fitting 32, and a distance between the abutting structure 3331C and the abutting cooperating structure 3313 gradually decreases during a movement of each of the clamping portions 3331 relative to the outer case 331 along the corresponding clamping direction D1. Preferably, the abutting structure 3331C and the clamping structure 3331B of each of the clamping portions 3331 are located on an inner side of each of the clamping portions 3331, and the clamping structure 3331B protrudes inwardly to exceed the abutting structure 3331C.

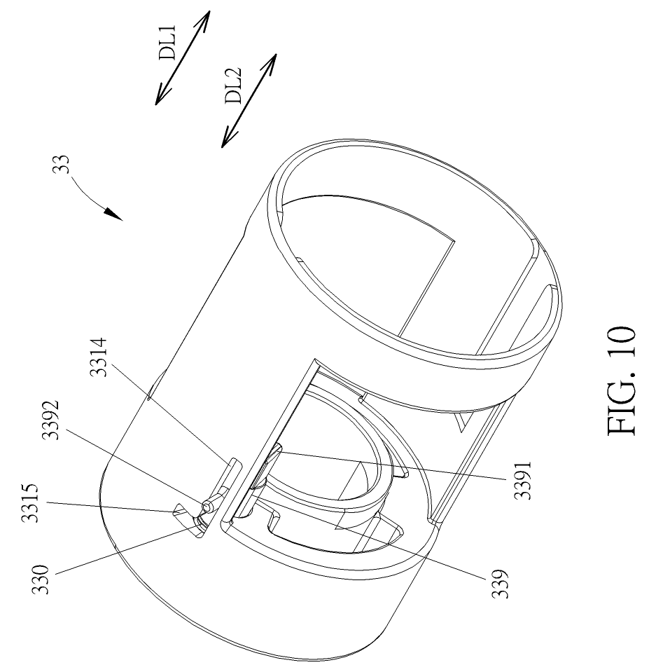

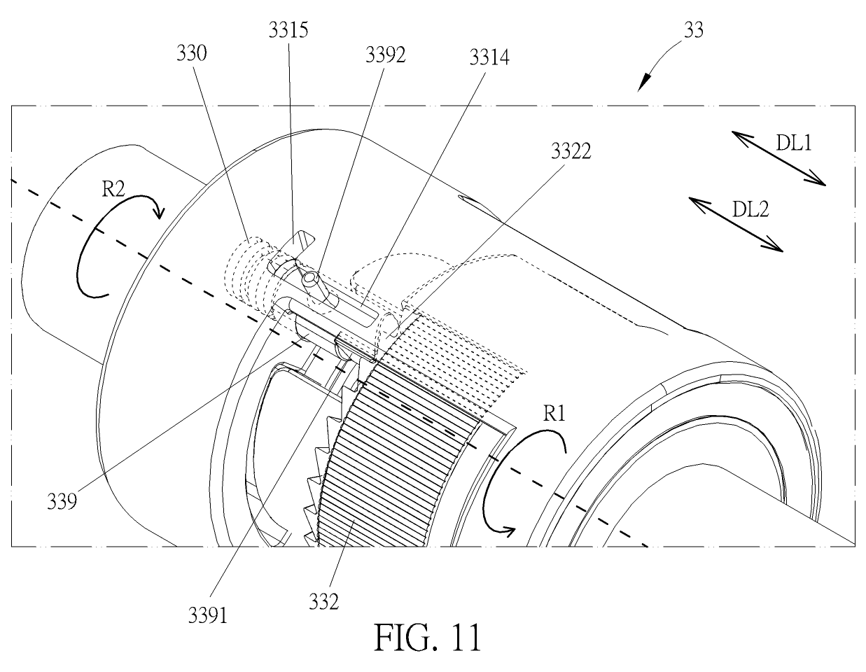

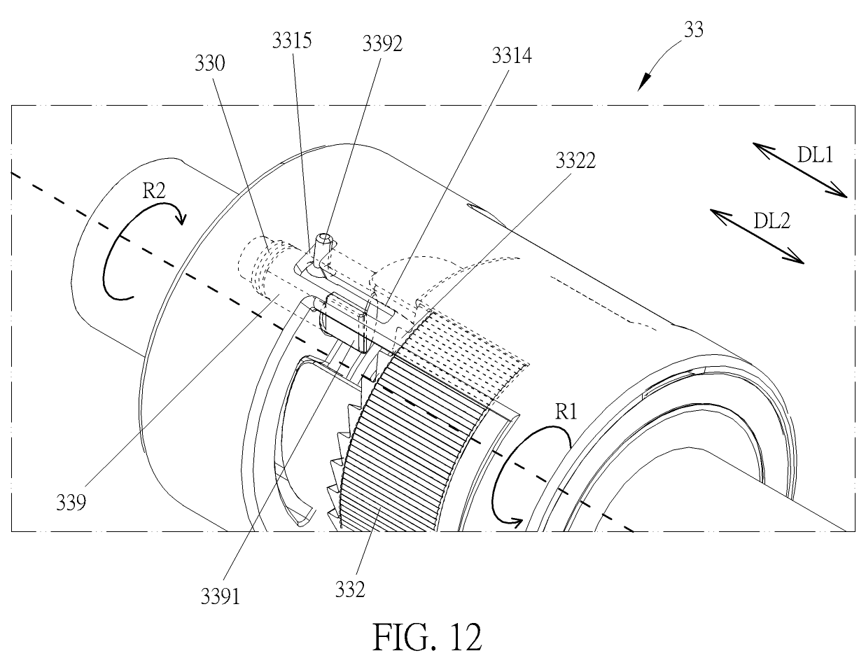

Please further refer to FIG. 6 to FIG. 8 and FIG. 10 to FIG. 12. FIG. 10 is another partial structural diagram of the anti-loosening mechanism 33 according to the embodiment of the present invention. FIG. 11 and FIG. 12 are partial enlarged structural diagrams of the anti-loosening mechanism 33 with an engaging component 339 at different positions according to the embodiment of the present invention. As shown in FIG. 6 to FIG. 8 and FIG. 10 to FIG. 12, in order to further ensure the pipe component 31 to be clamped by and between each of the clamping portions 3331 and the pipe fitting 32 stably, the anti-loosening mechanism 33 further includes an engaging component 339 and a resilient component 330. The engaging component 339 is movable relative to the outer case 331 between an interacting position as shown in FIG. 11 and a non-interacting position as shown in FIG. 12. The resilient component 330 abuts against the engaging component 339 and configured to drive the engaging component 339 to move toward the interacting position. The engaging component 339 includes a pawl structure 3391. The operating component 332 includes a ratchet structure 3322. When the engaging component 339 is located at the interacting position, the engaging component 339 allows a rotating movement of the operating component 332 along a first rotating direction R1 and restrains a rotating movement of the operating component 332 along a second rotating direction R2 opposite to the first rotating direction R1 by a cooperation of the pawl structure 3391 and the ratchet structure 3322. When the engaging component 339 is located at the non-interacting position, the pawl structure 3391 and the ratchet structure 3322 are separated from each other, thereby allowing not only the rotating movement of the operating component 332 along the first rotating direction R1 but also the rotating movement of the operating component 332 along the second rotating direction R2. It should be noticed that, the first rotating direction R1 and the second rotating direction R2 of the present invention are not limited to those illustrated in FIG. 11 and FIG. 12. Understandably, in another embodiment, the first rotating direction R1 and the second rotating direction R2 can be interchanged with each other, i.e., can be opposite to those of the aforementioned embodiment, and the pawl structure 3391 of the operating component 332 and the ratchet structure 3322 of the operating component 332 can be configured to have inclined surfaces with different oriented directions.

Specifically, the engaging component 339 further includes a sliding pin 3392. A sliding slot 3314 and a positioning slot 3315 are formed on the outer case 331. The positioning slot 3315 and the sliding slot 3314 are communicated and intersected with each other. A longitudinal direction DL2 of the sliding slot 3314 is parallel to the axial direction DL1 of the rotating axis R. The sliding pin 3392 passes through the sliding slot 3314 and is movable along the longitudinal direction DL2 of the sliding slot 3314, so as to move toward or away from the interacting position in response to the resilient recovery or deformation of the resilient component 330. When the sliding pin 3392 moves from the sliding slot 3314 into the positioning slot 3315, the engaging component 339 is positioned at the non-interacting position and prevented from being driven by the resilient component 330, so as to keep the pawl structure 3391 of the engaging component 339 separated from the ratchet structure 3322 of the operating component 332.

Detailed description of the anti-loosening mechanism 33 of the present invention is provided as follows. As shown in FIG. 3, FIG. 4, FIG. 11 and FIG. 12, when it is desired to use the anti-loosening mechanism 33 to secure the connection between the pipe component 31 and the pipe fitting 32, the pipe fitting 32 can be inserted into the pipe component 31, and then the outer case 331 can be rotatably mounted on the pipe fitting 32 by the second combining structure 3372 of the mounting component 337. Afterwards, the operating component 332 can be operated by hands to rotate relative to the outer case 331 along the first rotating direction R1 to drive each of the clamping portions 3331 to move relative to the outer case 331 along the corresponding clamping direction D1 from a position as shown in FIG. 3 to a position as shown in FIG. 4 by a cooperation of the driving structure 3321 and the driving cooperating structure 3331A, thereby achieving the pipe component 31 to be clamped by and between each of the clamping portions 3331 and the pipe fitting 32 for preventing disengagement of the pipe component 31 and the pipe fitting 32.

It should be noticed that when each of the clamping portions 3331 reaches the position as shown in FIG. 4, the abutting cooperating structure 3313 abuts against each of the abutting structures 3331C along the radial direction DR of the pipe fitting 32 to stop a further movement of each of the clamping portions 3331 along the corresponding clamping direction D1, thereby preventing any fracture or rupture of the pipe component 31 due to an excessive stress application. Furthermore, after each of the clamping portions 3331 moves from the position as shown in FIG. 3 to the position as shown in FIG. 4, the engaging component 339 can be driven to the interacting position as shown in FIG. 11 in response to a resilient force provided by the resilient component 330, thereby blocking and preventing the operating component 332 from rotating along the second rotating direction R2 by the engaging component 339, i.e., maintaining each of the clamping portions 3331 at the position as shown in FIG. 4 and preventing each of the clamping portions 3331 from moving along a releasing direction D2 opposite to the clamping direction D1. Additionally, if the operating component 332 is unintentionally released before each of the clamping portions 3331 reaches the position as shown in FIG. 4, the engaging component 339 also can be driven to the interacting position as shown in FIG. 11 in response to the resilient force provided by the resilient component 330 accordingly, so as to provide a foolproof effect of allowing the operating component 332 to continuously rotate along the first rotating direction R1 and preventing the operating component 332 from rotating along the second rotating direction R2 mistakenly by the cooperation of the pawl structure 3391 and the ratchet structure 3322.

On the other hand, when it is desired to disengage the pipe component 31 from the pipe fitting 32, the engaging component 339 can be operated to drive the sliding pin 3392 to move from the sliding slot 3314 into the positioning slot 3315 for maintaining the engaging component 339 at the non-interacting position as shown in FIG. 12 to keep the pawl structure 3391 of the engaging component 339 separated from the ratchet structure 3322 of the operating component 332. Afterwards, the operating component 332 can be operated by hands to rotate along the second rotating direction R2 to drive each of the clamping portions 3331 to move from the position as shown in FIG. 4 to the position as shown in FIG. 3 along the releasing direction D2. After each of the clamping portions 3331 moves from the position as shown in FIG. 4 to the position as shown in FIG. 3 along the releasing direction D2, each of the clamping portions 3331 does not exert any force on the pipe component 31, and therefore, it is easy to disengage the pipe component 31 from the pipe fitting 32.

In contrast to the prior art, in the present invention, it only has to rotate the operating component by hands to operate the anti-loosening mechanism without any additional tool, such as a screw driver. Therefore, the present invention provides improved operational convenience and is suitable for use in a confined mechanical space. Besides, in the present invention, the configuration, which utilizes the operating component to drive the clamping portion to clamp the pipe component between and by the clamping portion and the pipe fitting, not only prevents disengagement of the pipe component and the pipe fitting but also prevents any fracture or rupture of the pipe component due to stress concentration caused by an improper force application. Therefore, the present invention also provides enhanced reliability.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A anti-loosening mechanism for a pipe component and a pipe fitting at least partially removably inserted into the pipe component, the anti-loosening mechanism comprising:
an outer case configured to be removably mounted on the pipe fitting;
an operating component rotatable relative to the outer case around a rotating axis, the operating component comprising a driving structure; and
a clamping component at least partially movably sleeved inside the operating component, the clamping component comprising a plurality of clamping portions, each of the plurality of clamping portions comprising a driving cooperating structure, and when the operating component rotates relative to the outer case around the rotating axis, the operating component driving each of the plurality of clamping portions to move relative to the outer case along an clamping direction by a cooperation of the driving structure of the operating component and the driving cooperating structure of each of the plurality of clamping portions, such that the pipe component is clamped by and between each of the plurality of clamping portions and the pipe fitting.

2. The anti-loosening mechanism of claim 1, wherein the driving structure is an inner tapered threaded structure, the driving cooperating structure is an outer tapered threaded structure, the clamping direction is inclined relative to an axial direction and a radial direction of the pipe fitting, and an axial direction of the rotating axis is parallel to the axial direction of the pipe fitting.

3. The anti-loosening mechanism of claim 1, further comprising a plurality of buffering components, and each of the plurality of buffering components being disposed on each of the plurality of clamping portions and configured to abut against the pipe component.

4. The anti-loosening mechanism of claim 1, further comprising a guiding component configured to guide the plurality of clamping portions for preventing movements of the plurality of clamping portions along a circumferential direction of the pipe fitting.

5. The anti-loosening mechanism of claim 4, wherein a plurality of guiding notches are formed on the guiding component and configured to allow the plurality of clamping portions to at least partially pass therethrough.

6. The anti-loosening mechanism of claim 4, further comprising an auxiliary component disposed between the operating component and the guiding component and configured to prevent a frictional contact between the operating component and the guiding component.

7. The anti-loosening mechanism of claim 4, further comprising a positioning bracket configured to position the operating component and the guiding component on the outer case.

8. The anti-loosening mechanism of claim 7, wherein the positioning bracket comprises a lateral wall, a first wall and a second wall, the lateral wall is connected between and perpendicular to the first wall and the second wall, and the lateral wall, the first wall and the second wall of the positioning bracket cooperatively form a positioning space configured to position the operating component and the guiding component.

9. The anti-loosening mechanism of claim 8, wherein at least one first positioning structure is formed on the lateral wall, at least one second positioning structure is formed on the outer case, and the positioning bracket is positioned on the outer case by a cooperation of the at least one first positioning structure and the at least one second positioning structure.

10. The anti-loosening mechanism of claim 1, further comprising a mounting component, the mounting component comprising a first combining structure configured to separably combine with the outer case, and a second combining structure configured to separably combine with the pipe fitting.

11. The anti-loosening mechanism of claim 1, wherein each of the plurality of clamping portions further comprises an abutting structure, the outer case comprises an abutting cooperating structure, and the abutting structure is configured to abut against the abutting cooperating structure for preventing each of the plurality of clamping portions from moving relative to the outer case along the clamping direction.

12. The anti-loosening mechanism of claim 11, wherein the abutting structure of each of the plurality of clamping portions is disposed adjacent to an outer side of the abutting cooperating structure, the abutting cooperating structure is configured to abut against the abutting structure along a radial direction of the pipe fitting, and a distance between the abutting structure and the abutting cooperating structure decreases during a movement of each of the plurality of clamping portions relative to the outer case along the clamping direction.

13. The anti-loosening mechanism of claim 11, wherein each of the plurality of clamping portions further comprises a clamping structure, the abutting structure of each of the plurality of clamping portions and the clamping structure of each of the plurality of clamping portions are located on an inner side of each of the plurality of clamping portions, and the clamping structure protrudes inwardly to exceed the abutting structure.

14. The anti-loosening mechanism of claim 1, further comprising an engaging component movable relative to the outer case between an interacting position and a non-interacting position, the engaging component comprising a pawl structure, the operating component comprising a ratchet structure, and when the engaging component is located at the interacting position, the engaging component allowing a rotating movement of the operating component along a first rotating direction and restraining a rotating movement of the operating component along a second rotating direction opposite to the first rotating direction by a cooperation of the pawl structure and the ratchet structure.

15. The anti-loosening mechanism of claim 14, wherein the engaging component further comprises a sliding pin, a sliding slot is formed on the outer case, and the sliding pin passes through the sliding slot and is movable along a longitudinal direction of the sliding slot, so as to move toward or away from the interacting position.

16. The anti-loosening mechanism of claim 15, wherein a positioning slot is further formed on the outer case and communicated with the sliding slot, the positioning slot is intersected with the sliding slot, the longitudinal direction of the sliding slot is parallel to an axial direction of the rotating axis, and when the sliding pin moves from the sliding slot into the positioning slot, the engaging component is located at the non-interacting position and the pawl structure of the engaging component is separated from the ratchet structure for allowing the rotating movement of the operating component along the second rotating direction.

17. The anti-loosening mechanism of claim 14, further comprising a resilient component abutting against the engaging component and configured to drive the engaging component to move toward the interacting position.

18. The anti-loosening mechanism of claim 1, wherein a plurality of guiding slots are formed on the outer case and configured to allow the plurality of clamping portions to at least partially pass therethrough.

19. A pipe assembly comprising:
a pipe component;
a pipe fitting at least partially removably inserted into the pipe component; and
an anti-loosening mechanism comprising:
an outer case configured to be removably mounted on the pipe fitting;
an operating component rotatable relative to the outer case around a rotating axis, the operating component comprising a driving structure; and
a clamping component at least partially movably sleeved inside the operating component, the clamping component comprising a plurality of clamping portions, each of the plurality of clamping portions comprising a driving cooperating structure, and when the operating component rotates relative to the outer case around the rotating axis, the operating component driving each of the plurality of clamping portions to move relative to the outer case along an clamping direction by a cooperation of the driving structure of the operating component and the driving cooperating structure of each of the plurality of clamping portions, such that the pipe component is clamped by and between each of the plurality of clamping portions and the pipe fitting.

20. A cabinet system comprising:
a cabinet body;
an electronic device detachably mounted on the cabinet body, the electronic device comprising a connecting portion; and
a pipe assembly comprising:
a pipe component;
a pipe fitting at least partially removably inserted into the pipe component; and
an anti-loosening mechanism comprising:
an outer case configured to be removably mounted on the pipe fitting;
an operating component rotatable relative to the outer case around a rotating axis, the operating component comprising a driving structure; and
a clamping component at least partially movably sleeved inside the operating component, the clamping component comprising a plurality of clamping portions, each of the plurality of clamping portions comprising a driving cooperating structure, and when the operating component rotates relative to the outer case around the rotating axis, the operating component driving each of the plurality of clamping portions to move relative to the outer case along an clamping direction by a cooperation of the driving structure of the operating component and the driving cooperating structure of each of the plurality of clamping portions, such that the pipe component is clamped by and between each of the plurality of clamping portions and the pipe fitting.
